(19) United States
(12) Patent Application Publication
(10) Pub. No.: US 2023/0317809 A1
(43) Pub. Date: Oct. 5, 2023

(54) SELECTIVE PASSIVATION FOR EPI GROWTH IN PRESENCE OF METALLIC CONTACTS

(71) Applicant: Intel Corporation, Santa Clara, CA (US)

(72) Inventors: Sudipto NASKAR, Portland, OR (US); Shaun MILLS, Hillsboro, OR (US); Mauro J. KOBRINSKY, Portland, OR (US)

(21) Appl. No.: 17/710,791

(22) Filed: Mar. 31, 2022

(51) Int. Cl. H01L 29/423; H01L 29/06; H01L 29/417

(52) U.S. Cl. CPC H01L 29/42392; H01L 29/0673; H01L 29/41733

(57) ABSTRACT

Embodiments disclosed herein include semiconductor devices and methods of forming such devices. In an embodiment, the semiconductor device comprises a substrate, and a non-planar transistor with a source and a drain over the substrate. In an embodiment, a backside contact is provided to the source or drain through the substrate. In an embodiment, a residual liner is between the source or drain and the backside contact. In an embodiment, the residual liner does not extend entirely across an interface between the backside contact and the source or drain.

### TECHNICAL FIELD

Embodiments of the disclosure are in the field of semiconductor structures and processing and, in particular, to non-planar transistor devices with backside metal contacts.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant.

Variability in conventional and currently known fabrication processes may limit the possibility to further extend them into the 10 nanometer node or sub-10 nanometer node range. Consequently, fabrication of the functional components needed for future technology nodes may require the introduction of new methodologies or the integration of new technologies in current fabrication processes or in place of current fabrication processes.

In the manufacture of integrated circuit devices, multi-gate transistors, such as tri-gate transistors and gate-all-around (GAA) transistors, have become more prevalent as device dimensions continue to scale down. Tri-gate transistors and GAA transistors are generally fabricated on either bulk silicon substrates or silicon-on-insulator substrates. In some instances, bulk silicon substrates are preferred due to their lower cost and compatibility with the existing high-yielding bulk silicon substrate infrastructure.

Scaling multi-gate transistors has not been without consequence, however. As the dimensions of these fundamental building blocks of microelectronic circuitry are reduced and as the sheer number of fundamental building blocks fabricated in a given region is increased, the constraints on the semiconductor processes used to fabricate these building blocks have become overwhelming.

### BRIEF DESCRIPTION OF THE DRAWINGS

FIG. 1A is a cross-sectional illustration of a semiconductor device with an insulating liner between the source/drain regions and a sacrificial backside metal layer, in accordance with an embodiment.

FIG. 1B is a cross-sectional illustration of a semiconductor device with residual liner portions between the source/drain regions and the backside metal layer, in accordance with an embodiment.

FIG. 1C is a zoomed in cross-sectional illustration of the semiconductor device that more clearly illustrates the residual liners between the source/drain region and the backside metal layer, in accordance with an embodiment.

FIG. 2A is a cross-sectional illustration of a semiconductor device with a stack of nanowires or nanoribbons and source/drain openings over a sacrificial backside metal layer, in accordance with an embodiment.

FIG. 2B is a zoomed in cross-sectional illustration of the semiconductor device after a passivation layer is disposed over ends of the nanoribbons and the exposed surface of the spacers, in accordance with an embodiment.

FIG. 2C is a cross-sectional illustration of the semiconductor device after a liner is disposed over the sacrificial backside metal layer, in accordance with an embodiment.

FIG. 2D is a cross-sectional illustration of the semiconductor device after a source region and a drain region are grown in the openings above the liner, in accordance with an embodiment.

FIG. 2E is a cross-sectional illustration of the semiconductor device after the sacrificial metal layer is removed to expose a bottom surface of the liner, in accordance with an embodiment.

FIG. 2F is a cross-sectional illustration of the semiconductor device after the liner is partially removed to leave residual liners, in accordance with an embodiment.

FIG. 2G is a cross-sectional illustration of the semiconductor device after a backside metal layer is disposed in the openings below the source/drain regions, in accordance with an embodiment.

FIG. 3 is a cross-sectional illustration of a non-planar transistor device with residual liners between the source/drain regions and the backside metal layer, in accordance with an embodiment.

FIG. 4 illustrates a computing device in accordance with one implementation of an embodiment of the disclosure.

FIG. 5 is an interposer implementing one or more embodiments of the disclosure.

### DESCRIPTION OF THE EMBODIMENTS

Embodiments described herein comprise non-planar transistor devices with backside metal contacts. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

To provide context, backside metal contacts are increasingly used in order to provide power to transistor devices from the backside. However, the presence of the backside metal can result in some manufacturing difficulties. For example, when the metal is exposed during the epitaxial growth process used to form the source and drain regions, epitaxial growth will also nucleate from the metal surface. This can result in improperly formed source regions and drain regions. Accordingly, it is desirable to selectively grow the epitaxial source region and drain region from only the exposed ends of the nanowire or nanoribbons.

As such, embodiments disclosed herein include semiconductor devices that include a liner over the backside metal. The liner (e.g., an insulating material) covers the backside metal and prevents epitaxial growth. After the formation of the source region and the drain region, the backside metal may be etched out, and the liner is at least partially removed. A replacement backside metal can then be deposited in order to make an electrical connection to the epitaxially grown source region and drain region. In a particular embodiment, the liner may only be partially removed. That is, residual portions of the liner may persist into the final device structure. For example, residual liner portions may be provided at the corners of the interface between the source region or the drain region and the backside metal. In an embodiment, the liner may comprise silicon, oxygen, and carbon (e.g., SiOC) or any other suitable insulating material that inhibits epitaxial growth over the backside metal layer.

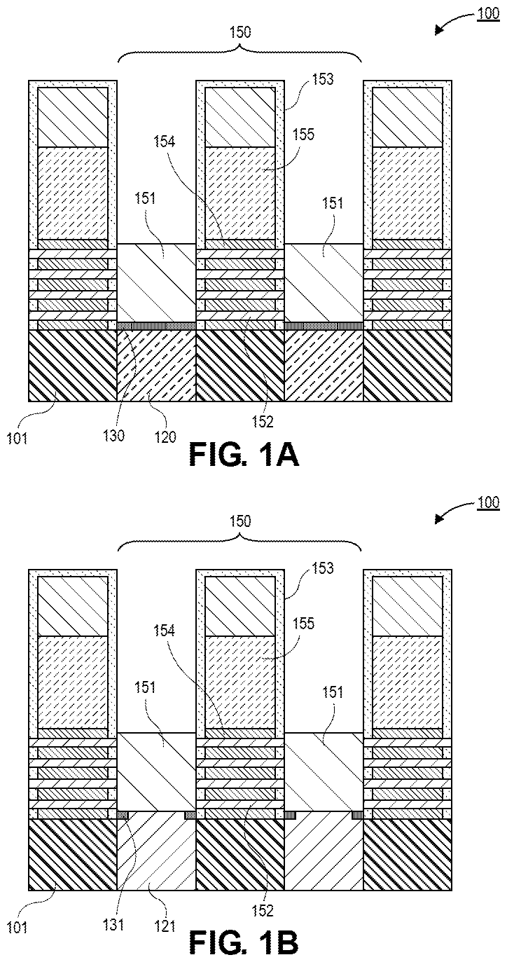

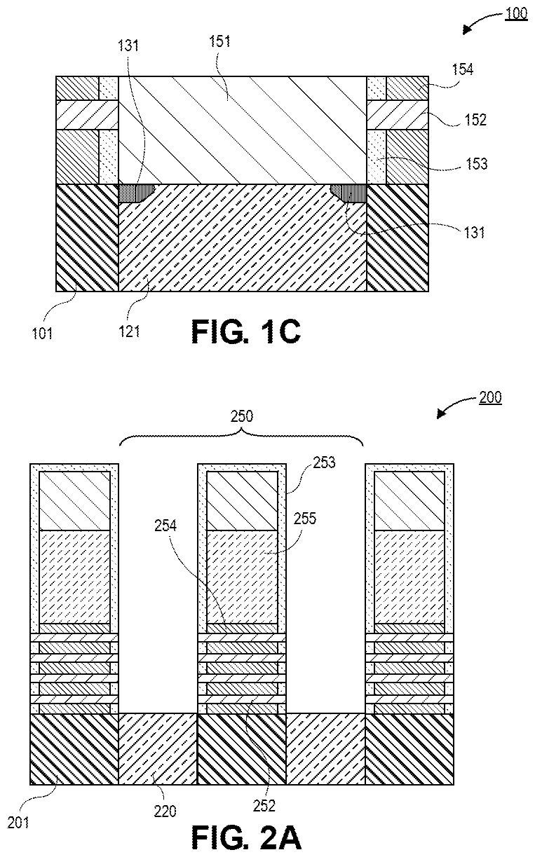

Referring now to FIG. 1A, a cross-sectional illustration of a semiconductor device 100 is shown, in accordance with an embodiment. In an embodiment, the semiconductor device 100 may comprise a transistor device 150 that is provided over a substrate 101. The transistor device 150 may be a non-planar transistor device. For example, a gate-all-around (GAA) device such as a nanowire device or a nanoribbon device is shown in FIG. 1A. However, other non-planar transistor device (e.g., tri-gate transistors) may also benefit from embodiments disclosed herein. The substrate 101 often includes a wafer or other piece of silicon or another semiconductor material. Suitable semiconductor substrates 101 include, but are not limited to, single crystal silicon, polycrystalline silicon and silicon on insulator (SOI), as well as similar substrates formed of other semiconductor materials, such as substrates including germanium, carbon, or group III-V materials. In other embodiments, the substrate 101 may include an insulating material that is provided over an underlying semiconductor substrate (not shown).

In an embodiment, the transistor device 150 may comprise a stack of one or more nanowires 152 or nanoribbons. The nanowires 152 may extend between spacers 153. Ends of the nanowires 152 may be exposed at the sidewall surfaces of the spacers 153. The nanowires 152 may be any suitable semiconductor material. For example, the nanowires 152 may comprise one or more of silicon, germanium, SiGe, GaAs, InSb, GaP, GaSb, InAlAs, InGaAs, GaSbP, GaAsSb, and InP. In the illustrated embodiment, a sacrificial gate structure 154 and 155 is provided between the spacers 153 around the nanowires 152. The sacrificial gate structure 154 and 155 may be replaced with a gate stack (e.g., a gate dielectric and a gate metal) in a subsequent processing operation, as will be described in greater detail below.

In an embodiment, semiconductor source/drain regions 151 may be provided at the ends of the nanowires 152. The semiconductor source/drain regions 151 may be epitaxially grown material. A selective epitaxial deposition process may be used, as will be described in greater detail below. In some implementations, the source/drain regions 151 may comprise a silicon alloy. In an embodiment, the silicon alloy may be in-situ doped silicon germanium, in-situ doped silicon carbide, or in-situ doped silicon. In alternate implementations, other silicon alloys may be used. For instance, alternate silicon alloy materials that may be used include, but are not limited to, nickel silicide, titanium silicide, cobalt silicide, and possibly may be doped with one or more of boron and/or aluminum.

In an embodiment, a liner 130 may be provided between the source/drain regions 151 and underlying backside metal layers 120. In an embodiment, the liner 130 prevents nucleation and growth of epitaxial semiconductor material from the underlying backside metal layers 120. The liner 130 may be an insulative material in some embodiments. In a particular embodiment, the liner 130 may comprise silicon, oxygen, and carbon (e.g., SiOC). The underlying backside metal layers 120 may be sacrificial metal layers. That is, the backside metal layers 120 may be removed in a subsequent processing operation and replaced with a permanent backside metal layer that contacts the source/drain regions 151 through the liner 130.

Referring now to FIG. 1B, a cross-sectional illustration of a semiconductor device 100 is shown, in accordance with an additional embodiment. In an embodiment, the semiconductor device 100 in FIG. 1B may be substantially similar to the semiconductor device 100 in FIG. 1A, with the exception of the liner 130 and the backside metal layers 120. Instead of a liner 130 that is provided across an entire top surface of the sacrificial backside metal layer 120, a residual portion 131 of the liner 130 is provided between the permanent backside metal layer 121 and the source/drain regions 151. In an embodiment, the residual portion 131 of the liner 130 may be located at the corners of the interface between the source/drain regions 151 and the backside metal layer 121. This architecture may be the result of incomplete etching of the liner 130. That is, the etching process may not be able to completely remove the liner 130, and shadowing effects may result in the presence of the residual portion 131 of the liner 130.

However, it is to be appreciated that sufficient etching of the liner 130 is provided in order to enable a good electrical connection between the source/drain region 151 and the backside metal layer 121. In an embodiment, the permanent backside metal layer 121 may comprise any suitable conductive material. For example, the backside metal layer 121 may comprise one or more of Cu, Al, Ti, Zr, Hf, V, Ru, Co, Ni, Pd, Pt, W, Ag, Au or alloys thereof. In the illustrated embodiment, a backside metal layer 121 is provided below both source/drain regions 151 in the transistor 150. In other embodiments, the backside metal layer 121 (and the residual portions 131 of the liner 130 may be provided over only one of the source/drain regions 151.

Referring now to FIG. 1C, a zoomed in cross-sectional illustration of the semiconductor device 100 is shown, in accordance with an embodiment. Particularly, the interface between a source/drain region 151 and a backside metal layer 121 is shown in FIG. 1C. As shown, the residual portions 131 of the liner 130 are positioned at the corners (i.e., outer edges) of the interface between the source/drain region 151 and the backside metal layer 121. In an embodiment, a top surface of the residual portions 131 may be substantially coplanar with a top surface of the backside metal layer 121. That is, the backside metal layer 121 may pass through a thickness of the residual portions 131 of the liner 130.

In an embodiment, the residual portions 131 may not have a uniform thickness along their length. For example, a first end of the residual portion 131 adjacent to the spacer 153 may have a first thickness, and a second end of the residual portion 131 opposite from the first end has a second thickness. As shown in FIG. 1C, the first thickness may be greater than a second thickness. In an embodiment, the reduction in thickness may be enable by a bottom surface of the residual portion 131 that slopes upward, while a top surface of the residual portion remains substantially flat. The architecture of the residual portion 131 may be dictated by the etching process used to remove the central portion of the liner 130.

While shown as having a non-uniform thickness, in other embodiments, the thickness of the liner 130 may be substantially uniform. As used herein “substantially uniform” may refer to a thickness that has a variation of 10% or less. For example, when a thickness of the liner 130 is 1 nm at one location, a thickness of the liner 130 that is considered substantially uniform across the entire length of the liner 130 may include thicknesses between 0.9 nm and 1.1 nm. Additionally, while the residual portion 131 of the liner 130 is shown as being thinner at an interior edge than at an outer edge in FIG. 1C, in other embodiments, the residual portion of the liner 130 may be thicker at an interior edge than at an outer edge.

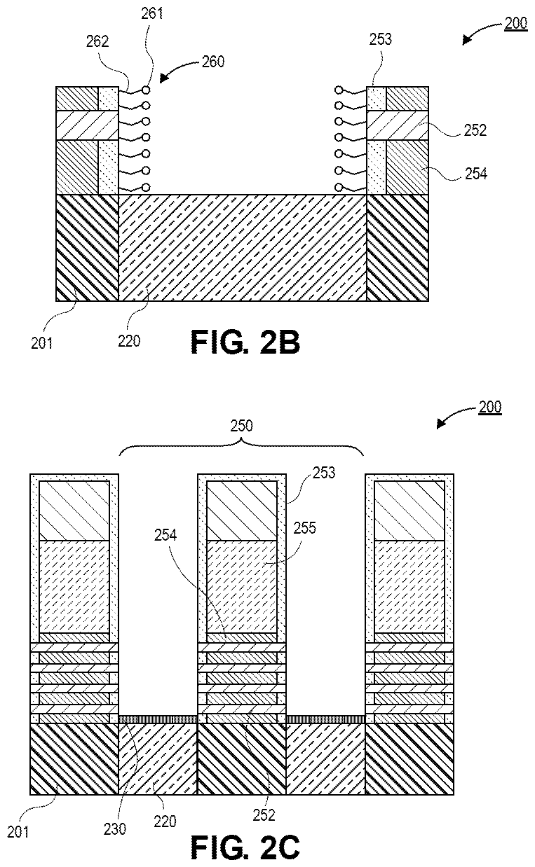

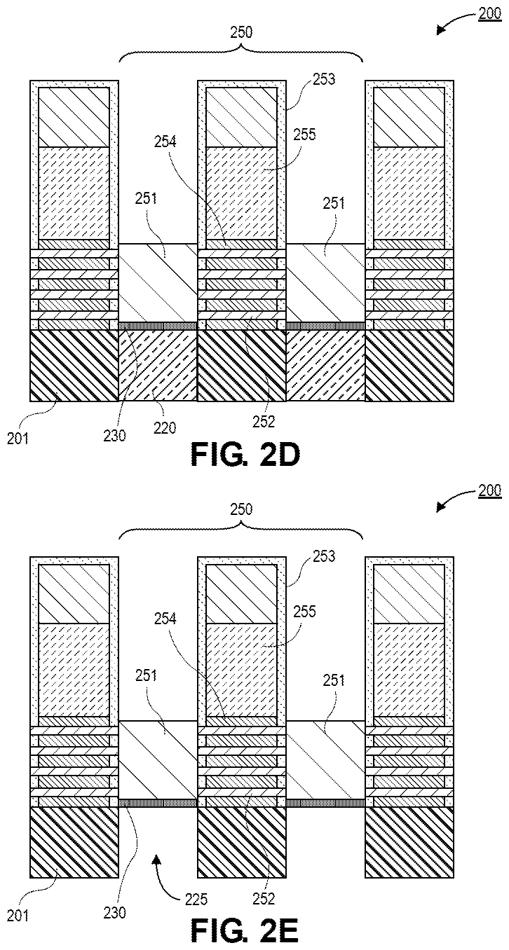

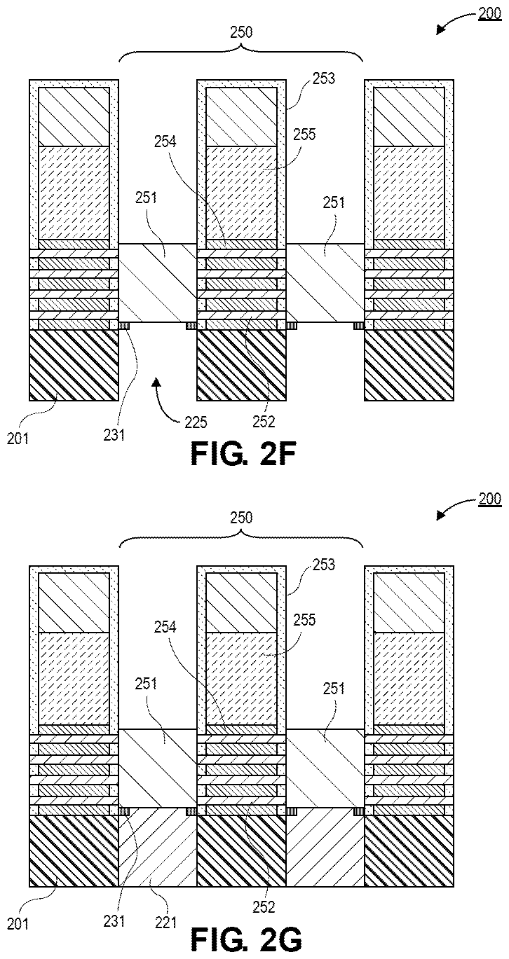

Referring now to FIGS. 2A-2G, a series of cross-sectional illustrations depicting a process for forming a transistor is shown, in accordance with an embodiment. In the illustrated embodiment, the transistor is shown as being a GAA transistor device. However, it is to be appreciated that other non-planar transistor architectures (e.g., tri-gate transistors) may also benefit from embodiments disclosed herein.

Referring now to FIG. 2A, a cross-sectional illustration of a semiconductor device 200 is shown, in accordance with an embodiment. In an embodiment, the semiconductor device 200 may include a transistor 250. The transistor 250 may include a stack of nanowires 252 or nanoribbons. The nanowires 252 may be surrounded by a sacrificial gate material 254 and 255. The nanowires 252 may pass through spacers 253 that are provided on the ends of the sacrificial gate material 254 and 255. The sacrificial gate material 254 and 255 may be any suitable material. For example, a polysilicon material or the like may be provided as the sacrificial gate material 254 around the nanowires 252.

In an embodiment, the transistor 250 may be provided over a substrate 201. In an embodiment, the substrate 201 may comprise a semiconductor material, such as silicon or the like. In other embodiments, the substrate 201 may comprise an insulating material, such as an oxide or the like that is provided over an underlying semiconductor substrate (not shown). In an embodiment, one or more backside metal layers 220 may be provided through the substrate 201. The backside metal layers 220 may be provided below cavities between the sacrificial gate structures 254 and 255. In a particular embodiment, the backside metal layers 220 are sacrificial layers. That is, the backside metal layers 220 may be removed in subsequent processing operations, as will be described in greater detail below. The backside metal layers 220 may include any suitable material.

Referring now to FIG. 2B, a zoomed in cross-sectional illustration of the semiconductor device 200 is shown, in accordance with an embodiment. In an embodiment, the semiconductor device 200 in FIG. 2B is shown after a passivation layer 260 is deposited. In an embodiment, the passivation layer 260 may include a plurality of molecules with a head group 261 and a tail group 262. The tail groups 262 preferentially adhere to the spacers 253 and the exposed portions of the nanowires 252. This leaves the backside metal layer 220 remaining exposed. The head groups 261 may comprise a structure that inhibits deposition of an insulating material used for the liner. Accordingly, the liner can be preferentially deposited over the backside metal layer 220 without also covering the nanowires 252 or the spacers 253. In a particular embodiment, the passivation layer 260 may comprise an aminosilane material, or any other molecule with a head group 261 and a tail group 262.

Referring now to FIG. 2C, a cross-sectional illustration of the semiconductor device 200 after the liner 230 is deposited is shown, in accordance with an embodiment. In an embodiment, the liner 230 may be selectively deposited over the backside metal layers 220. In an embodiment, the liner 230 may be deposited with a bottom up deposition process. In an embodiment, the deposition process may include a chemical vapor deposition (CVD) process, an atomic layer deposition (ALD) process, a plasma enhanced CVD (PE-CVD), a plasma enhanced ALD (PE-ALD), or the like. In an embodiment, a thickness of the liner 230 may be approximately 5 nm or less, or approximately 1 nm or less. As used herein, “approximately” refers to a value that is within ten percent of the stated value. For example, approximately 1 nm may refer to a range between 0.9 nm and 1.1 nm. In an embodiment, the liner 230 may be an insulating material. In a particular embodiment, the liner 230 may comprise silicon, oxygen, and nitrogen (e.g., SiOC). Though, it is to be appreciated that other insulating layers may also be used in various embodiments. After the liner 230 is deposited, the passivation layer 260 may be removed (e.g., with an etching process or the like).

Referring now to FIG. 2D, a cross-sectional illustration of the semiconductor device 200 after source/drain regions 251 are grown is shown, in accordance with an embodiment. While referred to as source/drain regions 251, it is to be appreciated that the regions 251 may either be a source region or a drain region, depending on how the transistor 250 is coupled to external circuitry. In an embodiment, the source/drain regions 251 may be grown with an epitaxial growth process. Since the backside metal 220 is shielded by the liner 230, the epitaxial semiconductor of the source/drain regions 251 will only nucleate and grow from the exposed surfaces of the nanowires 252. In an embodiment, the source/drain regions 251 may be semiconductor material such as silicon or a silicon alloy. The source/drain regions 251 may also be in-situ doped in some embodiments.

Referring now to FIGS. 2E, a cross-sectional illustration of the semiconductor device 200 after the backside metal layers 220 are removed is shown, in accordance with an embodiment. In an embodiment, the backside metal layers 220 may be removed with an etching process or the like. The liner 230 may serve as an etchstop layer in order to prevent etching into the source/drain regions 251. In an embodiment, removal of the backside metal layers 220 results in the formation of openings 225 below the source/drain regions 251. The openings 225 may be lined by the substrate 201. In an embodiment, the etching process is a wet etching process or a dry etching process.

Referring now to FIG. 2F, a cross-sectional illustration of the semiconductor device 200 after the liner 230 is etched is shown, in accordance with an embodiment. In an embodiment, the liner 230 may be etched with a wet or dry etching process. In an embodiment, the etching process is selective to the liner 230 over the source/drain regions 251. As such, etching through the liner 230 will not result in significant etching of the underlying source/drain regions 251.

In an embodiment, the etching process may not completely remove the liner 230. That is, residual portions 231 of the liner may remain on the source/drain regions 251. Particularly, the residual portions 231 may be located at the corner of the source/drain regions 251. In the illustrated embodiment, the residual portions 231 have a uniform thickness. However, in other embodiments, the residual portions 231 have a non-uniform thickness. For example, an outer edge of the residual portions 231 may be thicker than an inner edge of the residual portions 231. The bottom surface of the residual portions 231 may be sloped, while the top surface of the residual portions 231 that are in contact with the source/drain regions 251 may remain substantially flat.

Referring now to FIG. 2G, a cross-sectional illustration of the semiconductor device 200 after a replacement backside metal layer 221 is disposed in the openings 225 is shown, in accordance with an embodiment. In an embodiment, the replacement backside metal layer 221 may pass through the residual portions 231 of the liner 230 in order to contact the source/drain regions 251. Since the top of the backside metal layer 221 passes through the residual portions 231 of the liner 230, the top surface of the backside metal layer 221 may be narrower than a bottom surface of the backside metal layer. The contact may be a low contact resistance contact in order to improve the performance of the device. For example, a low contact resistance material may be deposited on the source/drain regions 251 and a fill metal may fill the remainder of the backside metal layer 221. In an embodiment, the backside metal layers 221 may include one or more of Cu, Al, Ti, Zr, Hf, V, Ru, Co, Ni, Pd, Pt, W, Ag, Au or alloys thereof.

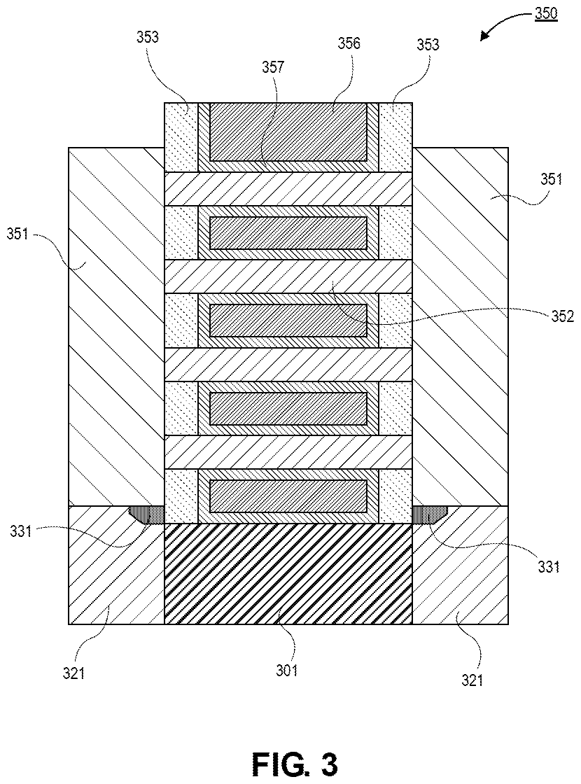

Referring now to FIG. 3, a cross-sectional illustration of a non-planar transistor 350 that includes residual portions 331 of a liner is shown, in accordance with an embodiment. In the illustrated embodiment, a GAA transistor device is shown. However, in other embodiments, a tri-gate transistor architecture may also be used. In an embodiment, the transistor 350 includes a stack of nanoribbons or nanowires 352. The nanowires 352 extend between spacers 353. Ends of the nanowires 352 may contact the source/drain regions 351.

In an embodiment, the source/drain regions 351 may be contacted by backside metal layers 321 that pass through a substrate 301. In an embodiment, both source/drain regions 351 include backside metal layer 321 contacts. In other embodiments, only one of the source/drain regions 351 may be contacted by a backside metal layer 321. In an embodiment, the backside metal layers 321 may pass through residual portions 331 of a liner. The residual portions 331 may be an insulative material. For example, the residual portions 331 may comprise silicon, oxygen, and carbon (e.g., SiOC). In an embodiment, the thickness of the residual portions 331 is non-uniform. For example, outer edges of the residual portions 331 may be thicker than inner edges of the residual portions 331.

In an embodiment, a gate stack may be provided over and around the nanowires 352. The gate stack may comprise a gate dielectric 357 and a gate electrode 356. The gate electrode 356 may include a workfunction metal and a fill metal. The gate dielectric 357 may be, for example, any suitable oxide such as silicon dioxide or high-k gate dielectric materials. Examples of high-k gate dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

When the workfunction metal of the gate electrode 356 will serve as an N-type workfunction metal, the gate electrode 356 preferably has a workfunction that is between about 3.9 eV and about 4.2 eV. N-type materials that may be used to form the metal gate electrode 356 include, but are not limited to, hafnium, zirconium, titanium, tantalum, aluminum, and metal carbides that include these elements, i.e., titanium carbide, zirconium carbide, tantalum carbide, hafnium carbide and aluminum carbide. When the workfunction metal of the metal gate electrode 356 will serve as a P-type workfunction metal, the gate electrode 356 preferably has a workfunction that is between about 4.9 eV and about 5.2 eV. P-type materials that may be used to form the metal gate electrode 356 include, but are not limited to, ruthenium, palladium, platinum, cobalt, nickel, and conductive metal oxides, e.g., ruthenium oxide.

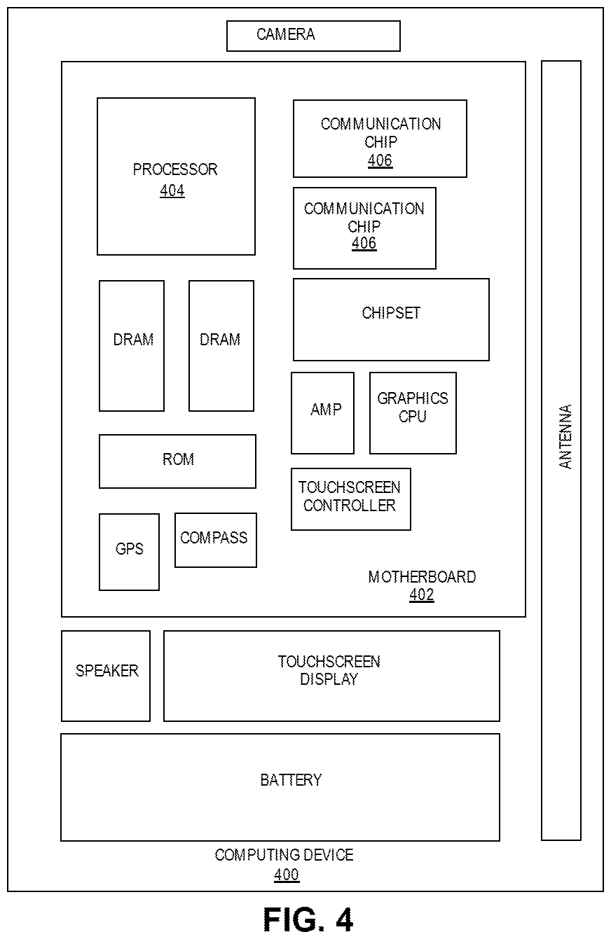

FIG. 4 illustrates a computing device 400 in accordance with one implementation of an embodiment of the disclosure. The computing device 400 houses a board 402. The board 402 may include a number of components, including but not limited to a processor 404 and at least one communication chip 406. The processor 404 is physically and electrically coupled to the board 402. In some implementations the at least one communication chip 406 is also physically and electrically coupled to the board 402. In further implementations, the communication chip 406 is part of the processor 404.

Depending on its applications, computing device 400 may include other components that may or may not be physically and electrically coupled to the board 402. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 406 enables wireless communications for the transfer of data to and from the computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 406 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others.

The processor 404 of the computing device 400 includes an integrated circuit die packaged within the processor 404. In an embodiment, the integrated circuit die of the processor may comprise a transistor device with a backside metal layer that is coupled to a source/drain region through a residual portion of a liner, as described herein. The term “processor” may refer to any device or portion of a device that processes electronic data from registers and/or memory to transform that electronic data into other electronic data that may be stored in registers and/or memory.

The communication chip 406 also includes an integrated circuit die packaged within the communication chip 406. In an embodiment, the integrated circuit die of the communication chip may comprise a transistor device with a backside metal layer that is coupled to a source/drain region through a residual portion of a liner, as described herein.

In further implementations, another component housed within the computing device 400 may comprise a transistor device with a backside metal layer that is coupled to a source/drain region through a residual portion of a liner, as described herein.

In various implementations, the computing device 400 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 400 may be any other electronic device that processes data.

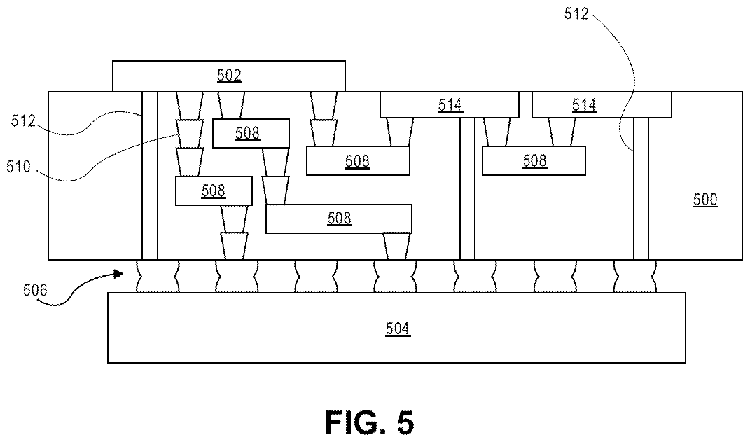

FIG. 5 illustrates an interposer 500 that includes one or more embodiments of the disclosure. The interposer 500 is an intervening substrate used to bridge a first substrate 502 to a second substrate 504. The first substrate 502 may be, for instance, an integrated circuit die. The second substrate 504 may be, for instance, a memory module, a computer motherboard, or another integrated circuit die. In an embodiment, one of both of the first substrate 502 and the second substrate 504 may comprise a transistor device with a backside metal layer that is coupled to a source/drain region through a residual portion of a liner, in accordance with embodiments described herein. Generally, the purpose of an interposer 500 is to spread a connection to a wider pitch or to reroute a connection to a different connection. For example, an interposer 500 may couple an integrated circuit die to a ball grid array (BGA) 506 that can subsequently be coupled to the second substrate 504. In some embodiments, the first and second substrates 502/504 are attached to opposing sides of the interposer 500. In other embodiments, the first and second substrates 502/504 are attached to the same side of the interposer 500. And in further embodiments, three or more substrates are interconnected by way of the interposer 500.

The interposer 500 may be formed of an epoxy resin, a fiberglass-reinforced epoxy resin, a ceramic material, or a polymer material such as polyimide. In further implementations, the interposer 500 may be formed of alternate rigid or flexible materials that may include the same materials described above for use in a semiconductor substrate, such as silicon, germanium, and other group III-V and group IV materials.

The interposer 500 may include metal interconnects 508 and vias 510, including but not limited to through-silicon vias (TSVs) 512. The interposer 500 may further include embedded devices 514, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 500. In accordance with embodiments of the disclosure, apparatuses or processes disclosed herein may be used in the fabrication of interposer 500.

Thus, embodiments of the present disclosure may comprise a transistor device with a backside metal layer that is coupled to a source/drain region through a residual portion of a liner.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.
Example 1: a semiconductor device, comprising: a substrate; a non-planar transistor with a source and a drain over the substrate; a backside contact to the source or drain through the substrate; and a residual liner between the source or drain and the backside contact, wherein the residual liner does not extend entirely across an interface between the backside contact and the source or drain.
Example 2: the semiconductor device of Example 1, wherein the residual liner is at an edge of the interface between the source or drain and the backside contact.
Example 3: the semiconductor device of Example 2, wherein the residual liner comprises a first portion and a second portion, wherein the first portion is separated from the second portion by the backside contact.
Example 4 semiconductor device of Examples 1-3, wherein a surface of the residual liner is substantially coplanar with an interface between the source or drain and the backside contact.
Example 5: the semiconductor device of Examples 1-4, wherein the residual liner has a non-uniform thickness.
Example 6: the semiconductor device of Example 5, wherein the residual liner has a first thickness adjacent to an edge of the backside contact and a second thickness on an opposite end of the residual liner from the edge of the backside contact, wherein the first thickness is greater than the second thickness.
Example 7: the semiconductor device of Examples 1-6, wherein the residual liner comprises silicon, oxygen, and carbon.
Example 8: the semiconductor device of Example 7, wherein the residual liner comprises SiOC.
Example 9: the semiconductor device of Examples 1-8, wherein the non-planar transistor comprises a gate-all-around (GAA) transistor.
Example 10: a method of forming a semiconductor device, comprising: providing a source or drain opening adjacent to a stack of nanoribbons that are provided within spacers, and wherein a sacrificial contact is below the source or drain opening; selectively disposing a passivation layer over the ends of the nanoribbons and the spacers; disposing a liner over the sacrificial contact, wherein the liner is blocked from depositing onto the nanoribbons or the spacers by the passivation layer; removing the passivation layer; growing a source region or a drain region in the source or drain opening; removing the sacrificial contact to form a backside opening; partially removing the liner, wherein residual liner portions remain at corners of the source or drain; and disposing a backside contact in the backside opening.
Example 11: the method of Example 10, wherein the passivation layer comprises a tail group and a head group.
Example 12: the method of Example 11, wherein the passivation layer comprises an aminosilane.
Example 13: the method of Examples 10-12, wherein the liner comprises silicon, oxygen, and carbon.
Example 14: the method of Example 13, wherein the liner comprises SiOC.
Example 15: the method of Examples 10-14, wherein the residual liner directly contacts the source or drain and the backside contact.
Example 16: the method of Examples 10-15, wherein a thickness of the residual liner portions is non-uniform.
Example 17: the method of Example 16, wherein a first thickness of an outer edge the residual liner portion is greater than a second thickness of an inner edge of the residual liner portion.
Example 18: the method of Examples 10-17, wherein the sacrificial contact comprises a material different than the backside contact.
Example 19: the method of Examples 10-18, wherein the source region or the drain region are grown with an epitaxial growth process.
Example 20: the method of Example 19, wherein the liner prevents epitaxial growth on the sacrificial contact.
Example 21: the method of Examples 10-20, further comprising: forming a gate stack around the nanoribbons.
Example 22: the method of Example 21, wherein the gate stack comprises a gate dielectric and a workfunction metal.
Example 23: an electronic system, comprising: a board; a package substrate coupled to the board; and a die coupled to the package substrate, wherein the die comprises: a source or a drain; a backside contact below the source or the drain; and a residual liner between the source or drain and the backside contact, wherein the residual liner is positioned at corners of an interface between the source or drain and the backside contact.
Example 24: the electronic system of Example 23, wherein the residual liner comprises silicon, oxygen, and carbon.
Example 25: the electronic system of Example 23, wherein the source or the drain is part of a gate-all-around (GAA) transistor.

What is claimed is:

1. A semiconductor device, comprising:
a substrate;
a non-planar transistor with a source and a drain over the substrate;
a backside contact to the source or drain through the substrate; and
a residual liner between the source or drain and the backside contact, wherein the residual liner does not extend entirely across an interface between the backside contact and the source or drain.

2. The semiconductor device of claim 1, wherein the residual liner is at an edge of the interface between the source or drain and the backside contact.

3. The semiconductor device of claim 2, wherein the residual liner comprises a first portion and a second portion, wherein the first portion is separated from the second portion by the backside contact.

4. The semiconductor device of claim 1, wherein a surface of the residual liner is substantially coplanar with an interface between the source or drain and the backside contact.

5. The semiconductor device of claim 1, wherein the residual liner has a non-uniform thickness.

6. The semiconductor device of claim 5, wherein the residual liner has a first thickness adjacent to an edge of the backside contact and a second thickness on an opposite end of the residual liner from the edge of the backside contact, wherein the first thickness is greater than the second thickness.

7. The semiconductor device of claim 1, wherein the residual liner comprises silicon, oxygen, and carbon.

8. The semiconductor device of claim 7, wherein the residual liner comprises SiOC.

9. The semiconductor device of claim 1, wherein the non-planar transistor comprises a gate-all-around (GAA) transistor.

10. A method of forming a semiconductor device, comprising:
providing a source or drain opening adjacent to a stack of nanoribbons that are provided within spacers, and wherein a sacrificial contact is below the source or drain opening;
selectively disposing a passivation layer over the ends of the nanoribbons and the spacers;
disposing a liner over the sacrificial contact, wherein the liner is blocked from depositing onto the nanoribbons or the spacers by the passivation layer;
removing the passivation layer;
growing a source region or a drain region in the source or drain opening;
removing the sacrificial contact to form a backside opening;
partially removing the liner, wherein residual liner portions remain at corners of the source or drain; and
disposing a backside contact in the backside opening.

11. The method of claim 10, wherein the passivation layer comprises a tail group and a head group.

12. The method of claim 11, wherein the passivation layer comprises an aminosilane.

13. The method of claim 10, wherein the liner comprises silicon, oxygen, and carbon.

14. The method of claim 13, wherein the liner comprises SiOC.

15. The method of claim 10, wherein the residual liner directly contacts the source or drain and the backside contact.

16. The method of claim 10, wherein a thickness of the residual liner portions is non-uniform.

17. The method of claim 16, wherein a first thickness of an outer edge the residual liner portion is greater than a second thickness of an inner edge of the residual liner portion.

18. The method of claim 10, wherein the sacrificial contact comprises a material different than the backside contact.

19. The method of claim 10, wherein the source region or the drain region are grown with an epitaxial growth process.

20. The method of claim 19, wherein the liner prevents epitaxial growth on the sacrificial contact.

21. The method of claim 10, further comprising:
forming a gate stack around the nanoribbons.

22. The method of claim 21, wherein the gate stack comprises a gate dielectric and a workfunction metal.

23. An electronic system, comprising:
a board;
a package substrate coupled to the board; and
a die coupled to the package substrate, wherein the die comprises:
a source or a drain;
a backside contact below the source or the drain; and
a residual liner between the source or drain and the backside contact, wherein the residual liner is positioned at corners of an interface between the source or drain and the backside contact.

24. The electronic system of claim 23, wherein the residual liner comprises silicon, oxygen, and carbon.

25. The electronic system of claim 23, wherein the source or the drain is part of a gate-all-around (GAA) transistor.
